(19) United States
(12) Patent Application Publication
(10) Pub. No.: US 2024/0223070 A1
(43) Pub. Date: Jul. 4, 2024

(54) CAPACITOR DETERIORATION DETECTION DEVICE AND CONVERTER SYSTEM

(71) Applicant: Fanuc Corporation, Minamitsuru-gun, Yamanashi (JP)

(72) Inventor: Yuya Nakagawa, Minamitsuru-gun, Yamanashi (JP)

(73) Assignee: Fanuc Corporation, Minamitsuru-gun, Yamanashi (JP)

(21) Appl. No.: 18/289,023

(22) PCT Filed: May 11, 2021
(86) PCT No.: PCT/JP2021/017920

§ 371 Date: Oct. 31, 2023

(51) Int. Cl. H02M 1/14; G01R 31/30; H02M 7/5387

(52) U.S. Cl. CPC H02M 1/143; G01R 31/3004; H02M 7/53871

(57) ABSTRACT

A capacitor deterioration detection device that detects deterioration of a filter capacitor which is provided in a filter connected to the AC side of a converter includes: a current measurement unit that measures current which flows in the filter capacitor; a calculation unit that uses the measurement value of the current which has been measured by the current measurement unit to calculate a parameter for determination of deterioration, and a determination unit that determines, on the basis of the result of a comparison between a reference value and the parameter for determination of deterioration which has been calculated by the calculation unit, whether or not the filter capacitor has deteriorated.

### CROSS REFERENCE TO RELATED APPLICATIONS

This is the U.S. National Phase application of PCT/JP2021/017920, filed May 11, 2021, the disclosure of this application being incorporated herein by reference in its entirety for all purposes.

### FIELD OF THE INVENTION

The present invention relates to a capacitor deterioration detection device and a converter system.

### BACKGROUND OF THE INVENTION

In a motor drive device that controls drive of a motor in a machine tool, a forging press machine, an injection molding machine, an industrial machine, or various types of robots, once AC power supplied from an AC power supply is converted to DC power by a converter (rectifier), the DC power is then converted to AC power by an inverter, and is supplied to the motor as motor drive power.

As a converter in a motor drive device, a PWM converter that has a power supply regeneration function to return regenerative power that is generated at the time of motor deceleration to the three-phase AC power supply side is widely used in addition to a converter using a diode rectification method. The PWM converter includes a bridge circuit that is formed by power devices each of which includes a diode and a switching element connected in inverse parallel to the diode. The PWM converter is capable of performing bidirectional power conversion between AC power on the AC side and DC power on the DC side by on/off operation of switching elements being controlled in accordance with a PWM control method.

Causing the switching elements in the PWM converter to perform on/off operation causes high-frequency ripple current to occur on the AC side of the PWM converter. It is common practice that, in order to absorb such high-frequency ripple current, a low-pass filter (hereinafter simply referred to as a “filter”) including a reactor for filter and a capacitor for filter is provided on the AC input side of the PWM converter.

For example, a capacitor capacitance estimation device that is a capacitor capacitance estimation device for estimating capacitance of a capacitor in an equipment system including a power supply, a capacitor that smooths DC voltage from the power supply, an inverter that generates AC voltage upon receiving supply of the smoothed DC voltage, and electrical equipment that operates upon receiving supply of the AC voltage and includes a filter design unit that generates a filter that, based on a load variation period that is a period with which a load applied to the electrical equipment varies, removes influence of the variation, a section signal acquisition unit that acquires a section signal in a predetermined period from an input signal that is included in the AC voltage and includes as a component a carrier frequency synchronized with a pulse width modulation (PWM) signal for controlling the inverter, a frequency domain conversion unit that, by dividing the section signal into a plurality of signals of a predetermined duration and converting each of the plurality of divided signals to a plurality of component values in the frequency domain, generates a plurality of pieces of frequency domain data, a carrier frequency component extraction unit that, by, in each of the plurality of pieces of frequency domain data, extracting a frequency component value corresponding to the carrier frequency from the plurality of component values and considering the extracted component value as a value for a duration matching a corresponding extracted signal, generates time series data that indicate a plurality of the extracted component values in time series, a filter application unit that, by applying the filter to the time series data, generates processed time series data, and a capacitor capacitance estimation unit that estimates the capacitance of the capacitor from the processed time series data has been known (see, for example, PTL 1).

For example, a motor drive device that includes an inverter that converts input DC voltage to AC voltage for driving a motor by an internal power device being on/off driven and outputs the AC voltage, a high-frequency current detection unit that detects high-frequency current from current that, by the AC voltage being applied to the motor via a motor power line, flows through the motor power line, and a floating capacitance estimation unit that estimates floating capacitance occurring in the motor power line and the motor, based on the high-frequency current detected by the high-frequency current detection unit is known (see, for example, PTL 2).

For example, a capacitance detection device that includes an electrode pair that includes a pair of electrodes arranged inside a compressor for compressing a refrigerant, a capacitor that is connected in series to the electrode pair, an inverter that has a first power line, the first power line being one of power lines driving the compressor, connected to one end of a measurement target unit formed by connecting the electrode pair and the capacitor in series and drives the compressor, and a voltage detection unit that measures voltage between the electrodes of the electrode pair is known (see, for example, PTL 3).

For example, a pattern capacitance measurement method of a circuit board, the method including arranging, on a back surface side of a circuit board to be inspected on the front surface of which a plurality of patterns are formed, an electrode common to all of the front surface patterns, bringing a probe into contact with the front surface pattern to be inspected and applying high level or low level voltage to the probe, applying high level or low level voltage to the common electrode and measuring current flowing through the front surface pattern, and calculating capacitance between the front surface pattern and the common electrode, in which an insulating layer is interposed between the circuit board and the common electrode is known (see, for example, PTL 4).

For example, a capacitor capacitance determination device of a power converter including a first power converter that converts single-phase AC to DC, a second power converter that converts DC to AC, and a DC intermediate circuit that is formed by a capacitor connected in parallel on the DC sides of the first and second power converters, the capacitor capacitance determination device including a means for estimating a capacitor capacitance value, based on the magnitude of AC voltage variation across the capacitor and AC input voltage or AC input current to the first power converter or command values of the AC input voltage or AC input current, is known (see, for example, PTL 5).

### PATENT LITERATURE

[PTL 1] WO 2019/239511
[PTL 2] JP 2019-135473A
[PTL 3] WO 2018/042809
[PTL 4] JPH10(1998)-142271A
[PTL 5] JPH10(1998)-014097A

### SUMMARY OF THE INVENTION

Since a capacitor for filter disposed in a filter connected to the AC side of a converter is used in an AC circuit, a non-polarized film capacitor is used as the capacitor for filter. The film capacitor is a capacitor formed by using plastic film as a dielectric material. The amount of heat generation from a film capacitor increases as the film capacitor deteriorates, and, in the worst case, there is a danger that the plastic film ignites. However, since, even when a film capacitor has deteriorated, no abnormality appears in operation of a converter connected to a filter including the film capacitor, there is a possibility that the filter will continue to be used without the deterioration of the film capacitor being noticed. Although deterioration of a film capacitor can be confirmed through reduction in capacitance, measurement of capacitance of a film capacitor cannot be performed during operation of a converter. Thus, an operator needs to determine occurrence or non-occurrence of deterioration by, after once cutting off a power supply on the AC input side of a filter, measuring the capacitance of a film capacitor by the operator himself/herself using a circuit tester, and this measurement and determination can be troublesome to carry out. Therefore, the development of a capacitor deterioration detection device capable of easily detecting deterioration of a capacitor for filter disposed in a filter connected to the AC side of a converter and a converter system including the capacitor deterioration detection device is in demand.

According to one aspect of the present disclosure, a capacitor deterioration detection device for detecting deterioration of a capacitor for filter disposed in a filter connected to an AC side of a converter includes a current measurement unit configured to measure current flowing through the capacitor for filter, a calculation unit configured to calculate a parameter for deterioration determination, using a measured value of the current measured by the current measurement unit, and a determination unit configured to determine occurrence or non-occurrence of deterioration of the capacitor for filter, based on a comparison result between the parameter for deterioration determination calculated by the calculation unit and a criterion value.

According to one aspect of the present disclosure, a converter system includes a converter configured to perform power conversion between AC power on an AC side and DC power on a DC side and the above-described capacitor deterioration detection device configured to detect deterioration of a capacitor for filter disposed in a filter connected to an AC side of the converter.

One aspect of the present disclosure provides a capacitor deterioration detection device capable of easily detecting deterioration of a capacitor for filter disposed in a filter connected to the AC side of a converter, and a converter system including the capacitor deterioration detection device to be achieved.

### BRIEF DESCRIPTION OF DRAWINGS

FIG. 1 is a diagram illustrating a capacitor deterioration detection device and a converter system including the capacitor deterioration detection device according to one embodiment of the present disclosure.

FIG. 2 is a diagram illustrating a case where, in the capacitor deterioration detection device and the converter system including the capacitor deterioration detection device according to the one embodiment of the present disclosure, a voltage measurement unit is omitted.

FIG. 3 is a flowchart illustrating deterioration determination processing using capacitance of a capacitor for filter in the capacitor deterioration detection device and the converter system including the capacitor deterioration detection device according to the one embodiment of the present disclosure.

FIG. 4 is a flowchart illustrating a variation of the deterioration determination processing using the capacitance of the capacitor for filter in the capacitor deterioration detection device and the converter system including the capacitor deterioration detection device according to the one embodiment of the present disclosure.

FIG. 5 is a diagram describing a loss tangent of a capacitor.

FIG. 6 is a flowchart illustrating deterioration determination processing using a loss tangent of the capacitor for filter in the capacitor deterioration detection device and the converter system including the capacitor deterioration detection device according to the one embodiment of the present disclosure.

### DETAILED DESCRIPTION OF EMBODIMENTS OF THE INVENTION

A capacitor deterioration detection device and a converter system will be described below with reference to the drawings. To facilitate understanding, the scales of the drawings are appropriately changed. An embodiment illustrated in the drawings is an example to embody the invention, and the invention is not limited to the illustrated embodiment.

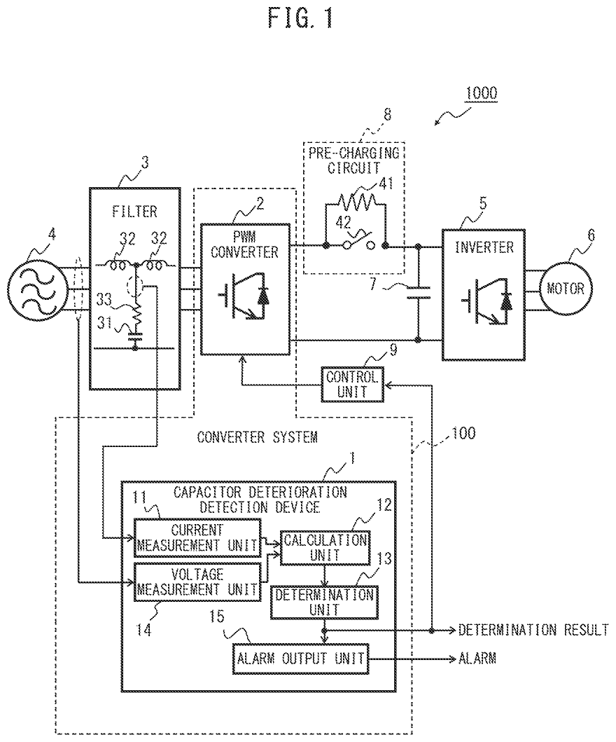

FIG. 1 is a diagram illustrating a capacitor deterioration detection device and a converter system including the capacitor deterioration detection device according to one embodiment of the present disclosure.

As an example, a case where a motor 6 is controlled by a motor drive device 1000 connected to an AC power supply 4 will be described. In the present embodiment, the type of the motor 6 is not limited to a specific type, and the motor 6 may be, for example, an induction motor or a synchronous motor. The numbers of phases of the AC power supply 4 and the motor 6 do not specifically limit the present embodiment, and the AC power supply 4 and the motor 6 may be, for example, of three-phase type or single-phase type. In the example illustrated in FIG. 1, the AC power supply 4 and the motor 6 are each assumed to be of three-phase type. Examples of the AC power supply 4 include a three-phase AC 400 V power supply, a three-phase AC 200 V power supply, a three-phase AC 600 V power supply, and a single-phase AC 100 V power supply. Examples of a machine in which the motor 6 is installed include a machine tool, a robot, a forging press machine, an injection molding machine, and an industrial machine.

As illustrated in FIG. 1, the motor drive device 1000 includes a filter 3, a converter system 100 according to one embodiment of the present disclosure, an inverter 5, a DC-link capacitor 7, a pre-charging circuit 8, and a control unit 9. In addition, the converter system 100 includes a PWM converter 2 and a capacitor deterioration detection device 1 according to one embodiment of the present disclosure.

The control unit 9 generates a PWM control signal for controlling switching operation of switching elements in the PWM converter 2 and outputs the generated PWM control signal to the PWM converter 2. It should be noted that, although not illustrated in the drawing, a power line for supplying the control unit 9 with power is a separate system from a power line for supplying the PWM converter 2 with power from the AC power supply 4. In other words, even before turning on the power of the PWM converter 2, power to drive the control unit 9 is supplied in preparation for operation at the time of turning on the power of the PWM converter 2.

The PWM converter 2 is formed as a rectifier that performs power conversion between AC power on the AC side and DC power on the DC side by switching operation of the switching elements being PWM-controlled based on a PWM control signal received from the control unit 9 and is capable of performing power supply regeneration. The PWM converter 2 includes a full-bridge circuit that is formed by power devices each of which includes a diode and a switching element connected in inverse parallel to the diode. Although examples of the switching element include an IGBT, an FET, a thyristor, a GTO, a transistor, and the like, the switching element may be another type of semiconductor element. In the example illustrated in FIG. 1, since the AC power supply 4 is defined to be a three-phase AC power supply, the PWM converter 2 is formed by a three-phase full-bridge circuit. When single-phase AC power is supplied from the AC power supply 4, the PWM converter 2 is formed by a single-phase bridge circuit. The PWM converter 2 selectively performs rectification operation of, by the control unit 9 controlling on/off operation of the switching elements in accordance with a PWM control method, converting AC power input from the AC side to DC power and outputting the DC power to the DC side and regenerative operation of, by the on/off operation of the switching elements, converting DC power on the DC side to AC power and outputting the AC power to the AC input/output side.

The filter 3 is connected to the AC side of the PWM converter 2.

The filter 3 has a function of absorbing high-frequency ripple current that occurs on the AC side of the PWM converter 2 by causing the switching elements in the PWM converter 2 to perform the on/off operation. The filter 3 includes a capacitor 31 for filter, two reactors 32, and a resistor 33. Since the filter 3 is connected to the AC side of the PWM converter, i.e. the capacitor 31 for filter is used in an AC circuit, a non-polarized film capacitor is used as the capacitor 31 for filter. Although examples of the capacitor 31 for filter include a film capacitor, the capacitor 31 for filter may be a ceramic capacitor.

In FIG. 1, to make the drawing concise, a connection relationship among the capacitor 31 for filter, the reactors 32, and the resistor 33 in the filter 3 is illustrated for only one phase. In the example illustrated in FIG. 1, since the AC power supply 4 is defined to be a three-phase AC power supply, the AC power supply 4 and the PWM converter 2 including a three-phase full-bridge circuit are electrically connected by power lines for three phases. In this case, a filter 3 including a capacitor 31 for filter, reactors 32, and a resistor 33 is disposed in each of the power lines for three phases, i.e. three filters 3 are disposed. More specifically, two reactors 32 that are series-connected to each other are disposed in a power line for each phase among power lines for three phases connecting the AC power supply 4 and the PWM converter 2. With respect to each of pairs of reactors 32 disposed in the power lines for three phases, one end of a set composed of a capacitor 31 for filter and a resistor 33 that are connected in series to each other is connected to a connection point between the two reactors 32. It should be noted that order of series connection in a set composed of a capacitor 31 for filter and a resistor 33 is only an example and the capacitor 31 for filter and the resistor 33 may be connected in series in an order other than the above-described order. One ends of such three sets of filters 3 to which the above-described power lines are not connected being connected to one another causes the three sets of filters 3 to be star-connected (Y-connected). It should be noted that although connection among the filters 3 was described using a case of star connection (Y connection) as an example, delta connection (A connection) may be formed by connecting one end of each filter 3 to which the above-described power line is not connected to a connection point between a capacitor 31 for filter and a resistor 33 and a capacitor 31 for filter of another filter 3.

It should be noted that when the AC power supply 4 is a single-phase AC power supply, one filter 3 including a capacitor 31 for filter, reactors 32, and a resistor 33 that have the above-described connection relationship is disposed in a single-phase power line that electrically connects the AC power supply 4 and a PWM converter 2 formed by a single-phase full-bridge circuit.

The DC-link capacitor 7 is disposed on the DC side of the PWM converter 2. The DC-link capacitor 7 has a function of suppressing a pulsation component of DC output from the PWM converter 2 as well as a function of accumulating DC power. The DC-link capacitor 7 is sometimes also referred to as a smoothing capacitor. Examples of the DC-link capacitor 7 include an electrolytic capacitor and a film capacitor.

The pre-charging circuit 8 configured to pre-charge the DC-link capacitor 7 is disposed between the PWM converter 2 and the DC-link capacitor 7. Instead of this configuration, the pre-charging circuit 8 may be disposed on the AC input/output side of the PWM converter 2.

The pre-charging circuit 8 includes a charging resistor 41 and a switch 42 for pre-charging connected in parallel to the charging resistor 41. The switch 42 for pre-charging is selectively switched between an open state that forms an electrical path via the charging resistor 41 and a closed state that forms a short circuit without going through the charging resistor 41. Although illustration of a control unit controlling opening/closing of the switch 42 for pre-charging is omitted, the control unit may be disposed in, for example, the control unit 9 that controls switching operation of the switching elements of the PWM converter 2. During a pre-charging period after turning-on of the power of the PWM converter 2 until start of drive of the motor 6, bringing the switch 42 for pre-charging into the open state causes DC current output from the PWM converter 2 to flow into the DC-link capacitor 7 through the charging resistor 41, as a result of which the DC-link capacitor 7 is charged. Since, during the pre-charging period, the DC current output from the PWM converter 2 goes through the charging resistor 41, occurrence of inrush current can be prevented. When the DC-link capacitor 7 is charged to a predetermined voltage, the switch 42 for pre-charging is switched from the open state to the closed state and the pre-charging is completed. Illustration of a detection unit that detects voltage across the DC-link capacitor 7 is omitted.

The inverter 5 is connected via the DC-link capacitor 7 to the DC side of the PWM converter 2. A circuit part that electrically connects the DC side of the PWM converter 2 and the DC side of the inverter 5 is referred to as “DC link”. The DC link is sometimes also referred to as “DC link unit”, “direct current link”, “direct current link unit”, “direct current bus”, or “direct current intermediate circuit”.

The inverter 5 is formed by a full-bridge circuit that includes switching elements and diodes connected in inverse parallel to the switching elements. Although examples of the switching element include an IGBT, an FET, a thyristor, a GTO, a transistor, and the like, the switching element may be another type of semiconductor element. In the example illustrated in FIG. 1, since the motor 6 is defined to be a three-phase AC motor, the inverter 5 is formed by a three-phase full-bridge circuit. When the motor 6 is a single-phase AC motor, the inverter 5 is formed by a single-phase bridge circuit.

The inverter 5 converts DC power in the DC link to AC power and supply the motor 6 on the AC side with the AC power and also converts AC power regenerated by deceleration of the motor 6 to DC power and returns the DC power to the DC link, by on/off operation of the internal switching elements being PWM-controlled based on a command from a higher-level control device (not illustrated). The motor 6 has speed, torque, or a position of a rotor controlled based on AC power supplied from the inverter 5. The higher-level control device controlling the inverter 5 may be formed by a combination of an analog circuit and an operation processing device or may be formed by only an operation processing device. Examples of an operation processing device that can constitute the higher-level control device controlling the inverter 5 include an IC, an LSI, a CPU, an MPU, and a DSP.

In order to cause the PWM converter 2 to normally operate, DC voltage having a value greater than or equal to a peak value of AC voltage from the AC power supply 4 needs to be output. When operation of the PWM converter 2 is to be started, first, the power of the PWM converter 2 is turned on and the DC-link capacitor 7 is pre-charged. As used herein, “turning-on of the power of the PWM converter 2” means “start of power supply from the AC power supply 4 to the PWM converter 2”. In other words, the power supply from the AC power supply 4 to the PWM converter 2 is not performed before the turning-on of the power of the PWM converter 2, and the power supply from the AC power supply 4 to the PWM converter 2 is performed after the turning-on of the power of the PWM converter 2. After the pre-charging of the DC-link capacitor 7 is completed, switching operation of the switching elements in the PWM converter 2 is performed and DC-link voltage that is DC voltage across the DC-link capacitor 7 is boosted to a voltage higher than a peak value of AC voltage on the AC power supply 4 side. Hereinafter, voltage boost of the DC-link capacitor 7 that is performed after the pre-charging of the DC-link capacitor 7 is completed is referred to as “initial voltage boost”. After the pre-charging and the initial voltage boost succeeding the pre-charging are completed, the PWM converter 2 transitions to a normal operation mode. In the normal operation mode, the PWM converter 2 operates as a rectifier that performs power conversion between the AC power on the AC side and the DC power on the DC side by switching operation of the switching elements being PWM-controlled based on a PWM control signal received from the control unit 9 and is capable of performing power supply regeneration.

The capacitor deterioration detection device 1 is a detection device that detects deterioration of the capacitors 31 for filter that are disposed in the filters 3 connected to the AC side of the PWM converter. Although, in the example illustrated in FIG. 1, the filter 3 is disposed in each of the three-phase power lines between the AC power supply 4 and the PWM converter 2 formed by a three-phase full-bridge circuit, the capacitor deterioration detection device 1 is capable of individually detecting deterioration of the capacitor 31 for filter with respect to each of the three filters 3.

In the one embodiment of the present disclosure, a period defined as a period from a time point at which the power of the PWM converter 2 is turned on and the pre-charging of the DC-link capacitor 7 starts to a time point at which the initial voltage boost starts is set as an “inspection period”. The capacitor deterioration detection device 1 detects deterioration of a capacitor 31 for filter, based on a measured value of current flowing through the capacitor 31 for filter during the inspection period. Although the inspection period is set as a period from a time point at which the pre-charging of the DC-link capacitor 7 starts to a time point at which the initial voltage boost starts, as described above, the inspection period may be set, as a variation of the setting, as a period from a time point at which the pre-charging of the DC-link capacitor 7 is completed to a time point at which the initial voltage boost starts.

The reason deterioration detection of the capacitor 31 for filter is performed based on a measured value of current flowing through the capacitor 31 for filter during the inspection period defined as a period from a time point at which the pre-charging starts to a time point at which the initial voltage boost starts as described above is as follows. Since, after the power of the PWM converter 2 is turned on, AC voltage is applied to each power line between the AC power supply 4 and the PWM converter 2, the AC voltage is also applied to a filter 3 that is disposed in each power line between the AC power supply 4 and the PWM converter 2, as a result of which current flows through the capacitor 31 for filter. Since, after a time point at which the initial voltage boost starts, switching operation of the switching elements of the PWM converter 2 is performed in an operation including the normal operation mode, high-frequency ripple current caused by the switching operation of the switching elements is caused to be included in currents flowing through the capacitors 31 for filter. In contrast, since, during a period from a time point at which the power of the PWM converter 2 is turned on to a time point at which the initial voltage boost starts, the switching operation of the switching elements of the PWM converter 2 is not performed, no high-frequency ripple current caused by the switching operation of the switching elements occurs and the currents flowing through the capacitors 31 for filter are formed in sine wave shapes. When the currents flowing through the capacitors 31 for filter have sine wave shapes not including high-frequency ripple current, capacitances of the capacitors 31 for filter can be accurately calculated using measured values of the currents. When a capacitor 31 for filter deteriorates, capacitance of the capacitor 31 for filter decreases and a loss tangent of the capacitor 31 for filter increases. Thus, in the one embodiment of the present disclosure, a parameter for deterioration determination (capacitance or a loss tangent) is calculated using a measured value of current flowing through each capacitor 31 for filter during the inspection period defined as a period from a time point at which the pre-charging starts to a time point at which the initial voltage boost starts, and occurrence or non-occurrence of deterioration of the capacitor 31 for filter is determined based on a comparison result between the parameter for deterioration determination and a predetermined criterion value.

The capacitor deterioration detection device 1 includes a current measurement unit 11, a calculation unit 12, a determination unit 13, a voltage measurement unit 14, and an alarm output unit 15.

The current measurement unit 11 measures current that flows through a capacitor 31 for filter. For example, a current sensor is disposed in a conductive wire to which the capacitor 31 for filter is connected, and the current measurement unit 11 acquires a measured value of current flowing through the capacitor for filter 31 via the current sensor.

The voltage measurement unit 14 measures power supply voltage on the AC side of the PWM converter 2. The voltage measurement unit 14 acquires a measured value of the power supply voltage via, for example, a voltage detection circuit that is built in the PWM converter 2. The “measured value of the power supply voltage” includes “line voltage between the AC power supply 4 and the filters 3” and a “frequency of the AC power supply 4”. It should be noted that the voltage measurement unit 14 may be omitted as in a variation, which will be described later.

The calculation unit 12 calculates a parameter for deterioration determination, using a measured value of current measured by the current measurement unit 11 during the inspection period defined as a period from a time point at which the pre-charging starts to a time point at which the initial voltage boost starts. Details of the parameter for deterioration determination will be described later.

The determination unit 13 determines occurrence or non-occurrence of deterioration of the capacitor 31 for filter, based on a comparison result between the parameter for deterioration determination calculated by the calculation unit 12 and a criterion value.

The alarm output unit 15 outputs an alarm when the capacitor 31 for filter is determined to have deteriorated by the determination unit 13.

An alarm output from the alarm output unit 15 is sent to, for example, a display unit (not illustrated), and the display unit performs display to notify an operator of, for example, “deterioration of a capacitor for filter”. Examples of the display unit include a single display device, a display device attached to the PWM converter 2, a display device attached to the converter system 100, a display device attached to the motor drive device 1000, a display device attached to the higher-level control device (not illustrated), and a display device attached to a personal computer or a mobile terminal. For example, an alarm output from the alarm output unit 15 is sent to a light-emitting device (not illustrated), such as an LED and a lamp, and the light-emitting device, by emitting light upon receiving an alarm, notifies an operator of “deterioration of a capacitor for filter”. For example, an alarm output from the alarm output unit 15 is sent to, for example, a sound device (not illustrated) and the sound device, by emitting sound, such as a voice and a sound from a speaker, a buzzer, or a chime, upon receiving an alarm, notifies the operator of “deterioration of a capacitor for filter”. Because of this configuration, the operator is able to easily and certainly recognize deterioration of a capacitor 31 and easily take action, such as replacing a deteriorated capacitor 31 for filter or a filter 3 including the deteriorated capacitor 31 for filter.

A determination result by the determination unit 13 is sent to the control unit 9, and, when a capacitor 31 for filter is determined to have deteriorated by the determination unit 13, the control unit 9 may control the PWM converter 2 to suspend power conversion or may perform protection operation in the motor drive device 1000. For example, when the motor 6 that the motor drive device 1000 drives is installed in a machine tool, examples of the protection operation include retract control, braking control, and drop prevention control. The retract control is control that, in a machine tool in which a workpiece and a tool are numerically controlled in synchronization with each other, retracts the workpiece and the tool to positions at which the workpiece and the tool do not interfere with each other while maintaining the synchronization between the workpiece and the tool at the time of power failure on the AC side, and the retract control enables breakage due to synchronization deviation between the workpiece and the tool to be prevented from occurring. The braking control is control that, in a machine tool in which coasting distance of a feed axis at the time of power failure on the AC side becomes a problem, performs deceleration and stopping lest collision occur due to coasting of the feed axis. The drop prevention control is control that, in a machine tool including a gravity axis, maintains current position of the gravity axis lest a workpiece or a tool be broken due to a drop of the gravity axis at the time of power failure.

Although, as described above, in the example illustrated in FIG. 1, the filter 3 is disposed in each of the three-phase power lines between the AC power supply 4 and the PWM converter 2 formed by a three-phase full-bridge circuit, the capacitor deterioration detection device 1 is capable of individually detecting deterioration of the capacitor 31 for filter with respect to each of the three filters 3. Therefore, three sets each of which is composed of the current measurement unit 11, the calculation unit 12, the determination unit 13, and the alarm output unit 15 are provided in such a manner that each set corresponds to one of the three filters 3. The capacitor deterioration detection device 1 detects deterioration of a capacitor 31 for filter with respect to each of the sets.

It should be noted that since, when the AC power supply 4 is a single-phase AC power supply, one filter 3 is disposed in a single-phase power line that electrically connects the AC power supply 4 and the PWM converter 2 formed by a single-phase full-bridge circuit, the capacitor deterioration detection device 1 includes only one set composed of the current measurement unit 11, the calculation unit 12, the determination unit 13, and the alarm output unit 15 and detects deterioration of the capacitor 31 for filter.

In the capacitor deterioration detection device 1, an operation processing device (processor) is provided. Examples of the operation processing device include an IC, an LSI, a CPU, an MPU, and a DSP. The operation processing device includes the current measurement unit 11, the calculation unit 12, the determination unit 13, the voltage measurement unit 14, and the alarm output unit 15. The above-described units included in the operation processing device are, for example, function modules that are achieved by computer programs executed in a processor. When, for example, the current measurement unit 11, the calculation unit 12, the determination unit 13, the voltage measurement unit 14, and the alarm output unit 15 are built in a form of computer program, causing the operation processing device to operate in accordance with the computer programs enables functions of the units to be achieved. Computer programs for executing the processing of the current measurement unit 11, the calculation unit 12, the determination unit 13, the voltage measurement unit 14, and the alarm output unit 15 may be provided by being recorded in a computer-readable recording medium, such as a semiconductor memory, a magnetic recording medium, and an optical recording medium. Alternatively, the current measurement unit 11, the calculation unit 12, the determination unit 13, the voltage measurement unit 14, and the alarm output unit 15 may be achieved as a semiconductor integrated circuit in which computer programs achieving the functions of the units are written.

Next, some forms of the parameter for deterioration determination and deterioration determination processing based on the parameter for deterioration determination will be described in order.

In a first form, the calculation unit 12 calculates capacitance of the capacitor 31 for filter as the parameter for deterioration determination and the determination unit 13 determines occurrence or non-occurrence of deterioration of the capacitor 31 for filter, based on a comparison result between the capacitance of the capacitor 31 for filter and a predetermined criterion value.

When a measured value of current flowing through a capacitor 31 for filter during the inspection period defined as a period from a time point at which the pre-charging starts to a time point at which the initial voltage boost starts is denoted by I, the amplitude of the power supply voltage on the AC side of the PWM converter 2 is denoted by V, and frequency of the power supply voltage is denoted by f, capacitance C of the capacitor 31 for filter is expressed by Equation 1.

$$\begin{matrix}[ Math 1 ] & \\ C = \frac{I}{2 π fV} & ( 1 )\end{matrix}$$

The measured value I of current flowing through the capacitor 31 for filter during the inspection period is measured by the current measurement unit 11. As the amplitude V of the power supply voltage and the frequency f of the power supply voltage, for example, measured values measured by the voltage measurement unit 14 are used. As the measured value I of the current measured by the current measurement unit 11 and the measured values of the amplitude V of the power supply voltage and the frequency of the power supply voltage measured by the voltage measurement unit 14, measured values measured at the same timing are used. Although effective values are preferably used for the measured value I of the current flowing through the capacitor 31 for filter and the amplitude V of the power supply voltage, peak values may be used though precision of the peak values is slightly inferior to precision of the effective values.

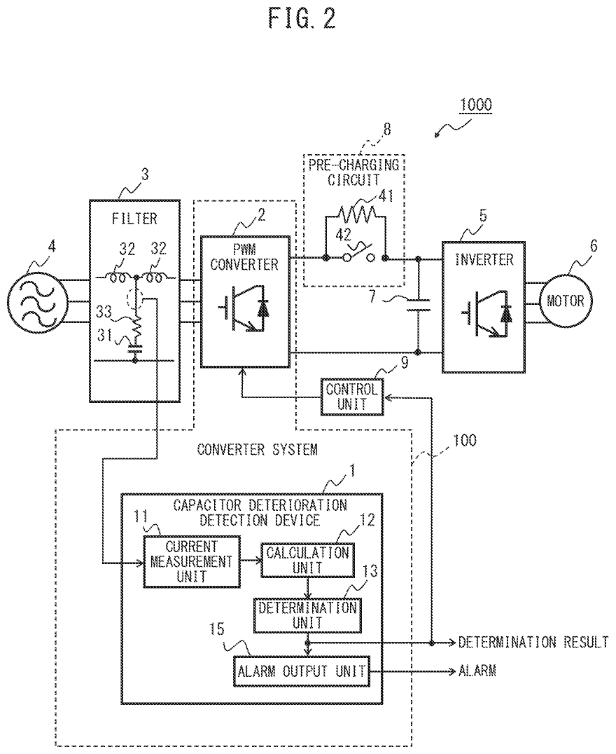

It should be noted that, in place of measured values of the amplitude V of the power supply voltage and the frequency f of the power supply voltage acquired by the voltage measurement unit 14, nominal values (i.e. constants) of the AC power supply 4 may be used for calculation of the capacitance C of the capacitor for filter based on Equation 1 under the assumption that the power supply voltage of the AC power supply 4 has little distortion. FIG. 2 is a diagram illustrating a case where, in the capacitor deterioration detection device and the converter system including the capacitor deterioration detection device according to the one embodiment of the present disclosure, the voltage measurement unit is omitted. When nominal values are used for calculation of the capacitance C of the capacitor for filter based on Equation 1, the voltage measurement unit 14 may be omitted from the capacitor deterioration detection device 1, as illustrated in FIG. 2.

The calculation unit 12 calculates the capacitance C of the capacitor 31 for filter serving as the parameter for deterioration determination in accordance with Equation 1, using a measured value of current flowing through the capacitor 31 for filter during the inspection period defined as a period from a time point at which the pre-charging starts to a time point at which the initial voltage boost starts. The capacitance C of the capacitor 31 for filter calculated by the calculation unit 12 is sent to the determination unit 13. The determination unit 13 determines occurrence or non-occurrence of deterioration of the capacitor 31 for filter, based on a comparison result between the capacitance of the capacitor 31 for filter calculated by the calculation unit 12 and a criterion value.

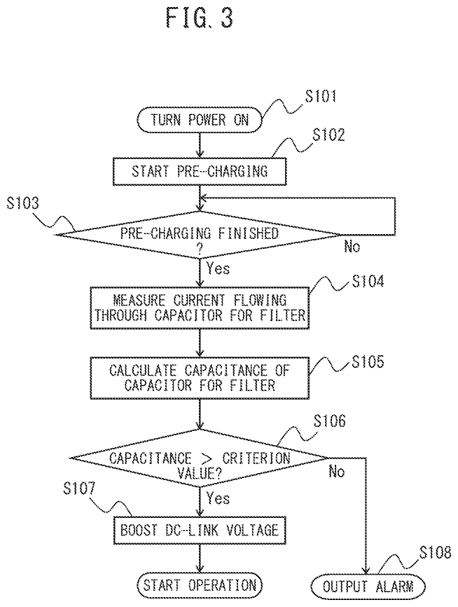

FIG. 3 is a flowchart illustrating deterioration determination processing using capacitance of a capacitor for filter in the capacitor deterioration detection device and the converter system including the capacitor deterioration detection device according to the one embodiment of the present disclosure. In the flowchart in FIG. 3, the inspection period is set to a period from a time point at which the pre-charging of the DC-link capacitor 7 is completed to a time point at which the initial voltage boost starts, as an example.

In step S101, the power of the PWM converter 2 is turned on.

Subsequently, in step S102, the pre-charging of the DC-link capacitor 7 starts, by the pre-charging circuit 8 bringing the switch 42 for pre-charging into the open state. At this stage, the switching elements of the PWM converter 2 have not performed switching operation (i.e. the switching elements are constantly in an off state), and the PWM converter 2 outputs DC current to the DC side by diode rectification. The DC current output from the PWM converter 2 flows into the DC-link capacitor 7 through the charging resistor 41, as a result of which the DC-link capacitor 7 is pre-charged. Since, during the pre-charging period, the DC current output from the PWM converter 2 goes through the charging resistor 41, occurrence of inrush current can be prevented.

In step S103, a control unit (not illustrated) that controls the pre-charging circuit 8 determines whether or not the pre-charging is completed. For example, the control unit that controls the pre-charging circuit 8 monitors a voltage value across the DC-link capacitor 7 and determines whether or not the pre-charging is completed based on whether or not the DC-link capacitor 7 is charged to a predetermined pre-charge voltage. When the DC-link capacitor 7 is charged to a predetermined pre-charge voltage, the control unit that controls the pre-charging circuit 8 switches the switch 42 for pre-charging from the open state to the closed state and notifies the capacitor deterioration detection device 1 that the pre-charging is completed. Subsequently, the process proceeds to step S104.

In step S104, the current measurement unit 11 measures current that flows through the capacitor 31 for filter. When, in the next step S105, the capacitance C of the capacitor 31 for filter is to be calculated using measured values of the amplitude V of the power supply voltage and the frequency f of the power supply voltage, the voltage measurement unit 14 also measures the amplitude V of the power supply voltage and the frequency f of the power supply voltage in step S104.

In step S105, the calculation unit 12 calculates the capacitance C of the capacitor 31 for filter serving as the parameter for deterioration determination, using the measured value I of the current flowing through the capacitor 31 for filter and values of the amplitude V of the power supply voltage and the frequency f of the power supply voltage. A value of the capacitance C of the capacitor 31 for filter calculated by the calculation unit 12 is sent to the determination unit 13.

In step S106, the determination unit 13 determines occurrence or non-occurrence of deterioration of the capacitor 31 for filter, based on a comparison result between the capacitance C of the capacitor 31 for filter calculated by the calculation unit 12 and a criterion value.

Examples of the criterion value that is used for the determination processing performed by the determination unit 13 in step S106 include an arbitrary capacitance that the operator sets, a minimum capacitance needed for operation of the filter 3, a capacitance immediately before the capacitor 31 for filter breaks down, a capacitance deviating from a tolerance range of capacitance that a manufacturer of the capacitor 31 for filter defines, and a lower limit of capacitance that is recommended by the manufacturer of the capacitor 31 for filter and at which the capacitor 31 for filter can be safely used. It should be noted that the criterion value may be stored in a rewritable storage unit (not illustrated) and be rewritable by an external device and can be changed to an appropriate value as needed even after the criterion value is once set. The storage unit only has to be formed by an electrically erasable/recordable nonvolatile memory, such as an EEPROM (registered trademark), or a high-speed readable/writable random access memory, such as a DRAM and an SRAM.

In step S106, when the capacitance C of the capacitor 31 for filter is determined to fall below the criterion value, the process proceeds to step S108 since the capacitor 31 for filter has deteriorated, and, when the capacitance C of the capacitor 31 for filter is not determined to fall below the criterion value, the process proceeds to step S107. The determination result by the determination unit 13 is sent to the alarm output unit 15 and the control unit 9.

In step S108, the alarm output unit 15 outputs an alarm. In addition, in step S108, the control unit 9 may control the PWM converter 2 to suspend power conversion or may perform the protection operation in the motor drive device 1000.

When the capacitance C of the capacitor 31 for filter is not determined to fall below the criterion value, the control unit 9 performs switching operation of the switching elements in the PWM converter 2 and thereby boosts DC-link voltage that is DC voltage across the DC-link capacitor 7 to a voltage higher than the peak value of the AC voltage on the AC power supply 4 side (initial voltage boost) in step S107. Subsequently, the PWM converter 2 transitions to the normal operation mode. In the normal operation mode, the PWM converter 2 operates as a rectifier that performs power conversion between the AC power on the AC side and the DC power on the DC side by switching operation of the switching elements being PWM-controlled based on a PWM control signal received from the control unit 9 and is capable of performing power supply regeneration.

As described above, during a period after the pre-charging is completed in step S103 until the initial voltage boost starts in step S107, the capacitance C of the capacitor 31 for filter is calculated using a measured value of current flowing through the capacitor 31 for filter, the measured value being measured by the current measurement unit 11, and occurrence or non-occurrence of deterioration of the capacitor 31 for filter is determined based on a comparison result between the capacitance C of the capacitor 31 for filter and the predetermined criterion value. Since no high-frequency ripple current is generated in the current flowing through the capacitor 31 for filter because switching operation of the switching elements in the PWM converter 2 is not performed during the inspection period after the pre-charging is completed in step S103 until the initial voltage boost starts in Step S107, the capacitance of the capacitor 31 for filter can be accurately calculated, as a result of which it is possible to accurately determine occurrence or non-occurrence of deterioration of the capacitor 31 for filter. According to the one embodiment of the present disclosure, since deterioration of each capacitor 31 for filter is automatically determined at the time of activation of the PWM converter 2, the operator does not need to determine occurrence or non-occurrence of deterioration by, after once cutting off the power supply on the AC input side of the filter, measuring the capacitance of the capacitor 31 for filter by the operator himself/herself using a circuit tester. As described above, according to the one embodiment of the present disclosure, it is possible to easily detect deterioration of the capacitors 31 for filter.

In the above-described embodiment, occurrence or non-occurrence of deterioration of each capacitor 31 for filter was determined based on a comparison between the capacitance of the capacitor 31 for filter and a criterion value. As a variation of the embodiment, occurrence or non-occurrence of deterioration of each capacitor 31 for filter may be determined based on a comparison result between a ratio of the capacitance of the capacitor 31 for filter calculated by the calculation unit 12 to an initial value and a criterion value.

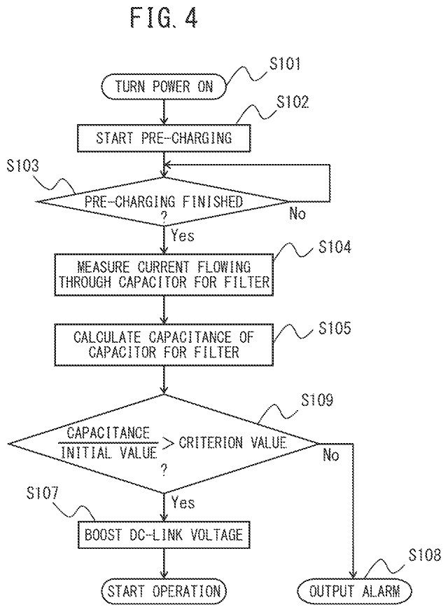

FIG. 4 is a flowchart illustrating a variation of the deterioration determination processing using the capacitance of a capacitor for filter in the capacitor deterioration detection device and the converter system including the capacitor deterioration detection device according to the one embodiment of the present disclosure. In the flowchart in FIG. 4, the inspection period is set to a period from a time point at which the pre-charging of the DC-link capacitor 7 is completed to a time point at which the initial voltage boost starts, as an example.

Steps S101 to S105 in FIG. 4 are the same as steps S101 to S105 that were described in FIG. 3.

In step S109 succeeding step S105, the determination unit 13 determines occurrence or non-occurrence of deterioration of the capacitor 31 for filter, based on a comparison result between a value calculated by dividing capacitance of the capacitor 31 for filter calculated by the calculation unit 12 by a capacitance initial value of the capacitor 31 for filter (i.e. a ratio of the capacitance of the capacitor 31 for filter calculated by the calculation unit 12 to the capacitance initial value) and a criterion value.

Examples of the capacitance initial value of the capacitor 31 for filter used in the determination processing performed by the determination unit 13 in step S109 include a capacitance measured at the time of shipment or manufacturing of the capacitor 31 for filter, a capacitance of the capacitor 31 for filter measured at the time of shipment or manufacturing of the PWM converter 2, a capacitance of the capacitor 31 for filter measured when the PWM converter 2 was driven for the first time after the PWM converter 2 was manufactured, and a nominal value of the capacitance of the capacitor 31 for filter.

The criterion value that is used for the determination processing performed by the determination unit 13 in step S109 is set to, for example, a value approximately several percent to a dozen or so percent lower than a ratio of the capacitance of the capacitor 31 for filter to the capacitance initial value in consideration of a minimum capacitance needed for operation of the filter 3, a capacitance immediately before the capacitor 31 for filter breaks down, a capacitance deviating from a tolerance range of capacitance that a manufacturer of the capacitor 31 for filter defines, and a lower limit of capacitance that is recommended by the manufacturer of the capacitor 31 for filter and at which the capacitor 31 for filter can be safely used. Numerical values indicated in the above description are only an example and may be values other than the above-described numerical values. It should be noted that the criterion value may be stored in a rewritable storage unit (not illustrated) and be rewritable by an external device and can be changed to an appropriate value as needed even after the criterion value is once set.

When, in step S109, a value calculated by dividing the capacitance C of the capacitor 31 for filter by the capacitance initial value of the capacitor for filter is determined to fall below the criterion value, the process proceeds to step S108 since the capacitor 31 for filter has deteriorated. When, in step S109, a value calculated by dividing the capacitance C of the capacitor 31 for filter by the capacitance initial value of the capacitor for filter is not determined to fall below the criterion value, the process proceeds to step S107. The determination result by the determination unit 13 is sent to the alarm output unit 15 and the control unit 9.

Steps S107 and S108 in FIG. 4 are the same as steps S107 and S108 that were described in FIG. 3.

As described above, in the present variation, it is also possible to easily detect deterioration of the capacitors 31 for filter.

In a second form, the calculation unit 12 calculates a loss tangent of the capacitor 31 for filter as the parameter for deterioration determination and the determination unit 13 determines occurrence or non-occurrence of deterioration of the capacitor 31 for filter, based on a comparison result between the loss tangent of the capacitor 31 for filter and a predetermined criterion value.

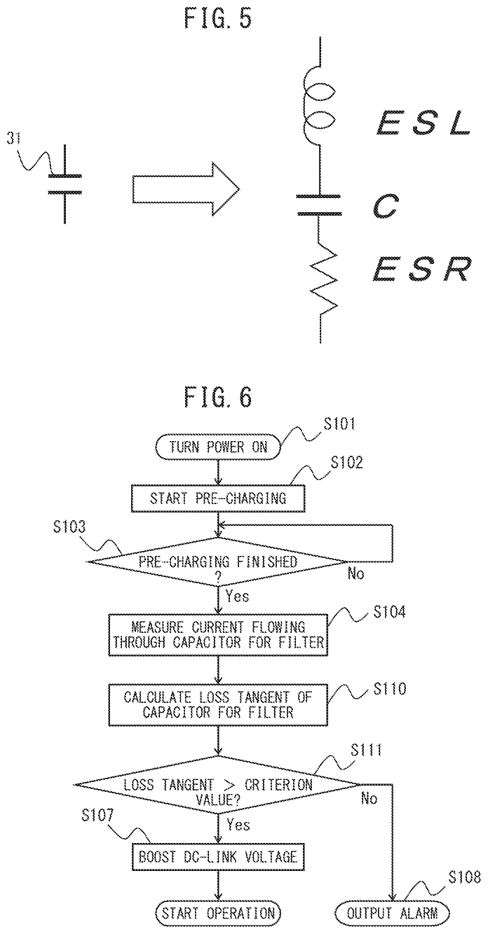

FIG. 5 is a diagram describing a loss tangent of a capacitor.

As illustrated in FIG. 5, a capacitor 31 for filter formed of a film capacitor or the like can be represented by capacitance C, equivalent series resistance ESR, and equivalent series inductance ESL. In a capacitor 31 for filter, dielectric loss and resistance loss due to a resistance component of an electrode and conductive wire occur. Although a phase difference between voltage applied to the capacitor 31 for filter and current flowing through the capacitor 31 for filter is ideally 90 degrees, a phase lag occurs due to influence of the losses and the phase difference deviates from 90 degrees. An angle of this lag (loss angle) is referred to as a loss tangent or tangent delta (tan δ). As deterioration of a film capacitor proceeds, the loss tangent tan δ increases. The calculation unit 12 calculates a loss tangent tan δ of the capacitor 31 for filter serving as the parameter for deterioration determination, using a measured value I of current measured by the current measurement unit 11 and a measured value V of voltage measured by the voltage measurement unit 14. The loss tangent tan δ of the capacitor 31 for filter calculated by the calculation unit 12 is sent to the determination unit 13. The determination unit 13 determines occurrence or non-occurrence of deterioration of the capacitor 31 for filter, based on a comparison result between the loss tangent tan δ of the capacitor 31 for filter calculated by the calculation unit 12 and a criterion value.

FIG. 6 is a flowchart illustrating deterioration determination processing using a loss tangent of a capacitor for filter in the capacitor deterioration detection device and the converter system including the capacitor deterioration detection device according to the one embodiment of the present disclosure. In the flowchart in FIG. 6, the inspection period is set to a period from a time point at which the pre-charging of the DC-link capacitor 7 is completed to a time point at which the initial voltage boost starts, as an example.

Steps S101 to S104 in FIG. 6 are the same as steps S101 to S104 that were described in FIG. 3.

In step S110, the calculation unit 12 calculates a loss tangent tan δ of the capacitor 31 for filter serving as the parameter for deterioration determination, using the measured value I of the current flowing through the capacitor 31 for filter and values of the amplitude V of the power supply voltage and the frequency f of the power supply voltage. A value of the loss tangent tan δ of the capacitor 31 for filter calculated by the calculation unit 12 is sent to the determination unit 13.

In step S111, the determination unit 13 determines occurrence or non-occurrence of deterioration of the capacitor 31 for filter, based on a comparison result between the loss tangent tan δ of the capacitor 31 for filter calculated by the calculation unit 12 and a criterion value.

Examples of the criterion value that is used for the determination processing performed by the determination unit 13 in step S111 include an arbitrary loss tangent that the operator sets, a minimum loss tangent needed for operation of the filter 3, a loss tangent immediately before the capacitor 31 for filter breaks down, a loss tangent deviating from a tolerance range of capacitance that the manufacturer of the capacitor 31 for filter defines, and an upper limit of the loss tangent that is recommended by the manufacturer of the capacitor 31 for filter and at which the capacitor 31 for filter can be safely used. It should be noted that the criterion value may be stored in a rewritable storage unit (not illustrated) and be rewritable by an external device and can be changed to an appropriate value as needed even after the criterion value is once set.

In step S111, when the loss tangent tan δ of the capacitor 31 for filter is determined to exceed the criterion value, the process proceeds to step S108 since the capacitor 31 for filter has deteriorated, and, when the loss tangent tan δ of the capacitor 31 for filter is not determined to exceed the criterion value, the process proceeds to step S107. The determination result by the determination unit 13 is sent to the alarm output unit 15 and the control unit 9.

Steps S107 and S108 in FIG. 6 are the same as steps S107 and S108 that were described in FIG. 3.

As described above, in the present variation, it is also possible to easily detect deterioration of the capacitors 31 for filter.

As described in the foregoing, according to the one embodiment of the present disclosure, the operator does not need to determine occurrence or non-occurrence of deterioration by, after once cutting off the power supply on the AC input side of the filter, measuring the capacitance of the capacitor 31 for filter by the operator himself/herself using a circuit tester as in a conventional manner. According to the one embodiment of the present disclosure, deterioration of each capacitor 31 for filter can be automatically detected at the time of activation of the PWM converter 2. Since no high-frequency ripple current is generated in the current flowing through the capacitor 31 for filter because switching operation of the switching elements in the PWM converter 2 is not performed during the inspection period after the pre-charging is completed until the initial voltage boost starts, the capacitance of the capacitor 31 for filter can be accurately calculated based on the current flowing through the capacitor 31 for filter, as a result of which it is possible to accurately determine occurrence or non-occurrence of deterioration of the capacitor 31 for filter.

It should be noted that the embodiment of the present disclosure can also be applied to a case where the converter is a diode rectifier in which a filter including a capacitor is connected to the AC side. In this case, when a capacitor 31 for filter is determined to have deteriorated by the determination unit 13 in the capacitor deterioration device 1, power conversion by the diode rectifier is suspended by, for example, cutting off supply of AC power to the diode rectifier through bringing an opening and closing device, such as an electromagnetic contactor, that is disposed on the AC side of the diode rectifier into an open state.

### REFERENCE SIGNS LIST

1 Capacitor deterioration detection device
2 PWM converter
3 Filter
4 AC power supply
5 Inverter
6 Motor
7 DC-link capacitor
8 Pre-charging circuit
9 Control unit
11 Current measurement unit
12 Calculation unit
13 Determination unit
14 Voltage measurement unit
15 Alarm output unit
31 Capacitor for filter
32 Reactor
33 Resistor
41 Charging resistor
42 Switch for pre-charging
100 Converter system
1000 Motor drive device

1. A capacitor deterioration detection device for detecting deterioration of a capacitor for filter disposed in a filter connected to an AC side of a converter, the capacitor deterioration detection device comprising:
a current measurement unit configured to measure current flowing through the capacitor for filter;
a calculation unit configured to calculate a parameter for deterioration determination, using a measured value of the current measured by the current measurement unit; and
a determination unit configured to determine occurrence or non-occurrence of deterioration of the capacitor for filter, based on a comparison result between the parameter for deterioration determination calculated by the calculation unit and a criterion value.

2. The capacitor deterioration detection device according to claim 1, wherein
the converter is a PWM converter, and
the calculation unit calculates the parameter for deterioration determination, using a measured value of the current measured by the current measurement unit during an inspection period until a time point at which switching operation of a switching element in the PWM converter for boosting voltage of a DC-link capacitor connected to a DC side of the PWM converter starts.

3. The capacitor deterioration detection device according to claim 2, wherein the inspection period is a period from a time point at which pre-charging of the DC-link capacitor is completed to a time point at which switching operation of a switching element in the PWM converter for further boosting voltage across the DC-link capacitor starts.

4. The capacitor deterioration detection device according to claim 1, wherein, when a measured value of the current measured by the current measurement unit during the inspection period is denoted by I, amplitude of power supply voltage on an AC side of the converter is denoted by V, and frequency of the power supply voltage is denoted by f, the calculation unit calculates, in accordance with
$$\begin{matrix}[ Math 1 ] & \\ C = \frac{I}{2 π fV} , & ( 1 )\end{matrix}$$
capacitance C of the capacitor for filter serving as the parameter for deterioration determination.

5. The capacitor deterioration detection device according to claim 4, wherein, when capacitance of the capacitor for filter calculated by the calculation unit falls below the criterion value, the determination unit determines that the capacitor for filter has deteriorated.

6. The capacitor deterioration detection device according to claim 4, wherein, when a value calculated by dividing capacitance of the capacitor for filter calculated by the calculation unit by a capacitance initial value of the capacitor for filter falls below the criterion value, the determination unit determines that the capacitor for filter has deteriorated.

7. The capacitor deterioration detection device according to claim 1 further comprising a voltage measurement unit configured to measure power supply voltage on an AC side of the converter,
wherein the calculation unit calculates a loss tangent serving as the parameter for deterioration determination, using a measured value of the current measured by the current measurement unit and a measured value of the power supply voltage measured by the voltage measurement unit during the inspection period.

8. The capacitor deterioration detection device according to claim 7, wherein, when the loss tangent calculated by the calculation unit exceeds the criterion value, the determination unit determines that the capacitor for filter has deteriorated.

9. The capacitor deterioration detection device according to claim 1 comprising an alarm output unit configured to output an alarm when the capacitor for filter is determined to have deteriorated by the determination unit.

10. A converter system comprising:
a converter configured to perform power conversion between AC power on an AC side and DC power on a DC side; and
the capacitor deterioration detection device according to claim 1 configured to detect deterioration of a capacitor for filter disposed in a filter connected to an AC side of the converter.

11. The converter system according to claim 10, wherein, when the capacitor for filter is determined to have deteriorated by the determination unit, the converter system suspends power conversion by the converter.
